(19) United States
(12) Patent Application Publication
(10) Pub. No.: US 2026/0134188 A1
(43) Pub. Date: May 14, 2026

(54) TRANSISTOR-LEVEL ROUTING

(71) Applicant: GDM Holding LLC, Mountain View, CA (US)

(72) Inventors: Hao Chen, Mountain View, CA (US); Chen-Hao Hsu, Mountain View, CA (US); Xiaoqing Xu, Mountain View, CA (US); Frederic Didier, Mountain View, CA (US); Laurent Perron, Mountain View, CA (US)

(21) Appl. No.: 18/947,911

(22) Filed: Nov. 14, 2024

(51) Int. Cl. G06F 30/3947; G06F 30/392

(52) U.S. Cl. CPC G06F 30/3947; G06F 30/392

(57) ABSTRACT

The technology includes transistor-level routing. According to one aspect, a method includes receiving a placement of transistors. Based on physical characteristics of the placement of transistors, the placement of transistors is partitioned into blocks. Respective routings for intra-partition nets of transistors for the blocks are determined. Respective routings for inter-partition nets of transistors for the blocks are determined.

### BACKGROUND

Integrated circuit (IC) development, involving design and fabrication, can be complicated and time consuming. The process can be particularly challenging with specialized integrated circuits, such as application-specific integrated circuits (ASICs) or system-on-chip (SoC) devices having many on-chip components such as transistors. There are a variety of approaches that have been employed to design such devices. In some approaches, a standard cell library may be used for each technology node. The library contains a set of cell structures that may comprise transistors and interconnections between them, in which the cell structures perform specific electronic logic functions such as a Boolean logic function (e.g., INVERT, AND, and OR) or a state or storage function. Standard cells provide a logic-level abstraction with fixed physical implementations, facilitating a standardized framework for very-large-scale integration (VLSI) design. Each cell is pre-characterized, and can be placed and routed at the transistor level. If a function to synthesize is not directly implementable in one cell, a combination of cells may be used to achieve it. However, this abstraction at the logic level may impose constraints on optimizing the ultimate physical layout.

Complexity of design rules may make the standard cell design exceedingly challenging for manual efforts. Therefore, standard cell design automation can be beneficial for handling complex design rules while optimizing performance, power, and area (PPA). Standard cell design automation is generally divided into two stages: transistor placement and in-cell routing. Transistor placement includes placing all transistors considering diffusion sharing to minimize the total cell area while optimizing the routing. In-cell routing includes connecting all transistor terminals (drain, gate and source) without design rule violations. It is critical to ensure the accessibility of standard cell pins.

Some approaches for in-cell routing have focused on the scale of standard cells (e.g., fewer than fifty transistors) for a given transistor placement. Other approaches are not able to provide transistor-level routing for a given large-scale transistor placement (e.g., hundreds or thousands of transistors). Because pitch scaling is limited, improvement of PPA from scaling is limited. As a result, design-technology co-optimization (DTCO) is increasingly important. DTCO comprises three main stages: technology, design enablement, and design. Design enablement bridges technology and design. Standard cell libraries enable the design process. Diversity and quality of standard cells may have an impact on PPA. However, pre-defined physical implementations of standard cells limit improvement of PPA.

### SUMMARY

Aspects of the technology adopt a design approach at the transistor level, rather than relying on pre-defined standard-cell configurations, in order to improve utilization of the potential of DTCO. Some other approaches include a transistor-level placement framework that directly places all transistors of a design without any standard cell abstraction. However, traditional transistor-level routing approaches may only be applied to a standard cell (i.e., in-cell routing) due to a long runtime. Therefore, a new routing framework is needed for a large-scale transistor placement of, for example, at least hundreds or thousands of transistors.

The technology relates to a transistor-level routing framework for a large-scale transistor placement that can route a given transistor placement while considering various complex design rules. Approaches disclosed herein include partitioning, lower-layer routing, and upper-layer routing. Partitioning leverages existing transistor placement results. Physical locations of transistors are considered in addition to their logical relationships, such as those within a standard cell, yielding improves in PPA relative to other approaches. A constraint programming-satisfiability (CP-SAT) formulation may be employed for transistor-level routing for a partition that optimizes the total wirelength while handling design rules and improving pin accessibility. This CP-SAT formulation for transistor-level routing can outperform other satisfiability modulo theories (SMT)-based approaches.

According to one aspect of the technology, a method includes receiving, by one or more processors, a placement of transistors; partitioning, by the one or more processors based on one or more physical characteristics of the placement of transistors, the placement of transistors into a plurality of blocks; determining, by the one or more processors, respective routings for intra-partition nets of transistors for the plurality of blocks; and determining, by the one or more processors, respective routings for inter-partition nets of transistors for the plurality of blocks.

In an example, the one or more physical characteristics of the placement of transistors may include at least one of locations of transistors within the placement of transistors, a quantity of transistors of the placement of transistors, or a spacing between transistors of the placement of transistors.

Alternatively or additionally to the above, the one or more physical characteristics of the placement of transistors may include a connectivity of transistors of the placement of transistors.

Alternatively or additionally to the above, determining the respective routings for the intra-partition nets of transistors may include determining respective escape pins for the plurality of blocks. Here, determining the respective routings for the inter-partition nets of transistors may include determining respective connections of the escape pins for the inter-partition nets of transistors.

Alternatively or additionally to the above, determining the respective routings for the intra-partition nets of transistors may include generating respective routing grid graphs for the inter-partition nets of transistors. Here, determining the respective routings for the intra-partition nets of transistors further may include generating respective flow networks corresponding to the routing grid graphs. Determining the respective routings for the intra-partition nets of transistors may further include generating respective Steiner trees corresponding to the flow networks.

Alternatively or additionally to the above, determining the respective routings for the intra-partition nets of transistors may be based on connectivity constraints.

Alternatively or additionally to the above, determining the respective routings for the intra-partition nets of transistors may be based on design rule constraints. Here, the design rule constraints may include at least one of minimum area constraints, end-of-line (EOL) spacing constraints, via spacing constraints, or parallel run length (PRL) spacing constraints.

Alternatively or additionally to the above, the method may include, responsive to determining the respective routings for the intra-partition and the respective routings for the inter-partition nets, generating a routing result. Here, the method may further include causing fabrication of an integrated circuit using the routing result.

According to another aspect of the technology, a system is provided that comprises memory configured to store a placement of transistors for a semiconductor device to be fabricated, and one or more processors operatively coupled to the memory. The one or more processors are configured to: partition, based on one or more physical characteristics of the placement of transistors, the placement of transistors into a plurality of blocks; determine respective routings for intra-partition nets of transistors for the plurality of blocks; and determine respective routings for inter-partition nets of transistors for the plurality of blocks.

In an example, the one or more physical characteristics of the placement of transistors may include at least one of locations of transistors within the placement of transistors, a quantity of transistors of the placement of transistors, or a spacing between transistors of the placement of transistors.

Alternatively or additionally to the above, the one or more physical characteristics of the placement of transistors may include a connectivity of transistors of the placement of transistors.

Alternatively or additionally to the above, determining the respective routings for the intra-partition nets of transistors may include determining respective escape pins for the plurality of blocks. Here, the one or more processors may be configured to determine the respective routings for the inter-partition nets of transistors by being configured to determine respective connections of the escape pins for the inter-partition nets of transistors.

Alternatively or additionally to the above, the one or more processors may be configured to determine the respective routings for the intra-partition nets of transistors by being configured to generate respective routing grid graphs for the inter-partition nets of transistors. Here, the one or more processors may be configured to determine the respective routings for the intra-partition nets of transistors by being further configured to generate respective flow networks corresponding to the routing grid graphs. The one or more processors may be configured to determine the respective routings for the intra-partition nets of transistors by being further configured to generate respective Steiner trees corresponding to the flow networks.

Alternatively or additionally to the above, the one or more processors may be configured to determine the respective routings for the intra-partition nets of transistors based on connectivity constraints.

Alternatively or additionally to the above, the one or more processors may be configured to determine the respective routings for the intra-partition nets of transistors based on design rule constraints. Here, the design rule constraints may include at least one of minimum area constraints, end-of-line (EOL) spacing constraints, via spacing constraints, or parallel run length (PRL) spacing constraints.

Alternatively or additionally to the above, the one or more processors may be configured to, responsive to determination of the respective routings for the intra-partition and the respective routings for the inter-partition nets, generate a routing result. Here, the one or more processors may be further configured to cause fabrication of the semiconductor device using the routing result.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates an integrated circuit design flow in accordance with aspects of the technology.

FIG. 2 illustrates an example system that may be employed with aspects of the technology.

FIG. 3 illustrates an example of a transistor placement in accordance with aspects of the technology.

FIG. 4 illustrates an example of partitioning of a transistor placement in accordance with aspects of the technology.

FIG. 5 illustrates an example of lower-layer routing of a partitioned transistor placement in accordance with aspects of the technology.

FIG. 6 illustrates an example of a routing grid graph in accordance with aspects of the technology.

FIG. 7 illustrates an example of a flow network including super-nodes in accordance with aspects of the technology.

FIG. 8 illustrates an example of a Steiner tree based on a flow network in accordance with aspects of the technology.

FIG. 9A illustrates an example of minimum area constraints for a vertex in accordance with aspects of the technology. FIG. 9B illustrates examples of edge combinations for that vertex in accordance with aspects of the technology.

FIG. 10A illustrates an example of EOL spacing constraints for a wire edge in accordance with aspects of the technology. FIG. 10B illustrates examples of wire edges that need to be constrained in accordance with aspects of the technology.

FIG. 11 illustrates an example method in accordance with aspects of the technology.

### DETAILED DESCRIPTION

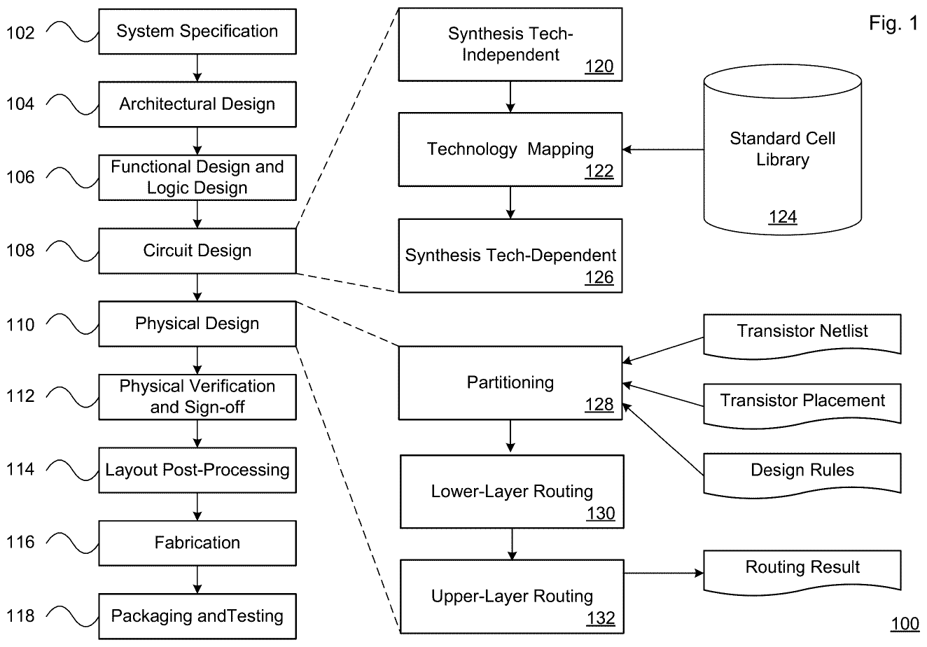

FIG. 1 illustrates an exemplary integrated circuit design flow 100 for use with aspects of the technology, including generating a circuit design and/or fabricating an integrated circuit that incorporates determining potential manufacturing defects in a mask pattern. As shown, the design flow may include preparing a system specification at block 102, such as to identify system-level requirements for the integrated circuit. The system specification is intended to capture the overall goal of the desired integrated circuit. This may include determining the device's cost, performance, general architecture, how off-chip communication will be conducted, etc. The process flow may also include performing architectural design at block 104. At this stage, the design's architecture and its layout are determined by design engineers. This can include integration of memory management, analog and/or mixed-signal components, on-device and external communication, any power constraints, choice of process technology and/or layer stacks, etc.

The process flow continues with performing functional design and logic design at block 106, and performing circuit design at block 108. Functional design may include refinement of the design's specification to achieve the functional behavior of the desired system. Logic design involves adding the design's structure to a behavioral representation of the desired design. Here, considerations include logic minimization, performance enhancement, as well as testability. This stage may consider problems associated with test vector generation, error detection and correction, and the like. By way of example, the functional design and logic design may include generating a behavioral model description (e.g., using HDL) and floor-planning. During circuit design, logic blocks are replaced by corresponding electronic circuits, which may include devices such as resistors, capacitors, and/or transistors. At this stage, circuit simulation may be performed in order to verify timing behavior and other constraints of the system. A Spice tool or other program may be used for circuit simulation.

Once the circuit design is complete, physical design may be performed at block 110 (e.g., component and wiring placement and routing), followed by physical verification and sign-off at block 112 (e.g., to obtain GDSII information with shapes to form the masks used to create the layers for fabricating the integrated circuit). During physical design, the actual layout of the integrated circuit is performed. Here, all of the components are placed and interconnected using metal interconnections. During this stage, according to aspects of the disclosed technology the system may perform partitioning, lower-layer routing, and upper-layer routing to generate a routing result, alternatively or additionally to any other layout operations. A circuit design that is able to pass testing of a circuit simulator in the circuit design stage may be found to be faulty after it has been packaged, e.g., due to geometric design rule issues. Thus, physical design rules are followed to ensure correctness during chip fabrication. Errors may include short or open circuits, open channels, or other issues may result when physical design rules are not followed. During physical verification and sign-off, the system performs any verification steps that are required before chip manufacturing. This can include design rule checking and correction, timing simulation, electromagnetic simulation, etc.

Layout post-processing occurs at block 114, then fabrication at block 116, and the packaging and testing at block 118. At block 114, the layout post-processing may include geometry processing before actual manufacturing, e.g., any dummy fill insertion, correction for optical proximity, mask optimization, etc. Fabrication comprises semiconductor manufacturing, which includes stages such as lithography patterning (masking), baking or annealing, etching, etc. Then the raw die of the chip is inserted into a package and I/O pins are connected to the package at block 118. Testing of the chip also occurs at this stage.

As shown, in the circuit design phase of block 108, the process may involve technology-independent synthesis at block 120. This step involves transferring the circuit definitions, such as register-transfer-level (RTL) descriptions, into generic data structures such as And-inverter graph (AIG), and optimizing the circuit in terms of nodes and levels. At block 122, technology mapping is performed based on information from a standard cell library 124. This step involves mapping the generic optimized AIG descriptions into real, manufacturable standard cells included in the standard cell library. From this, technology-dependent synthesis is then performed at block 126. This step further optimizes the circuit defined in the gate-level netlist in terms of power, performance and area, using standard-cell-based definitions from block 122.

As shown, in the physical design phase of block 110, the process may involve partitioning at block 128, followed by lower-layer routing at block 130, and upper-layer routing at block 132. The partitioning process may receive information including a transistor netlist, transistor placement details and/or design rules. Upon completion of the routing, the system may generate routing results.

### Example Integrated Circuit Development System

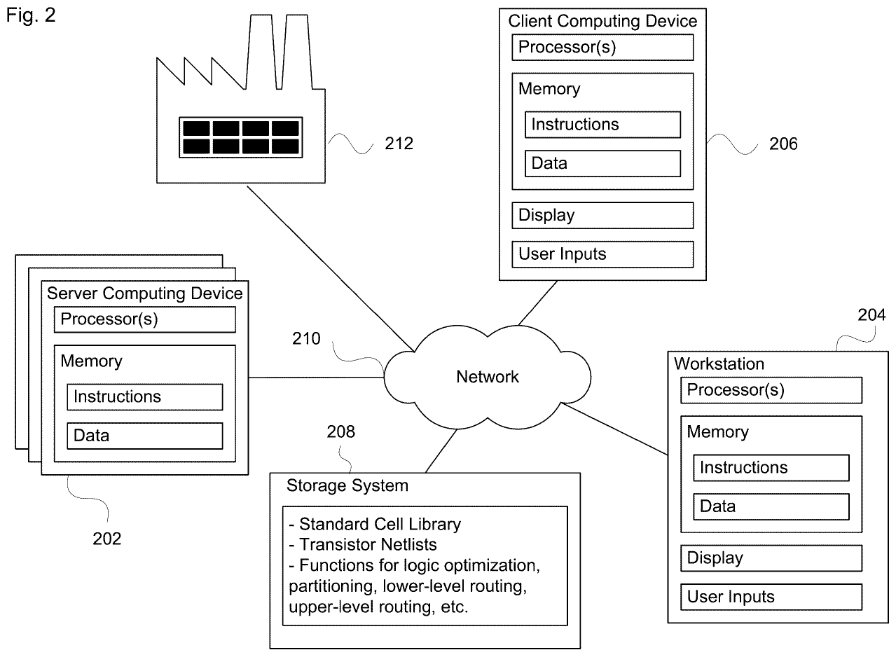

One example of a system for performing circuit design and fabrication is shown in FIG. 2. In particular, FIG. 2 is a functional diagram, of an example system 200 that includes a plurality of computing devices 202, 204, 206 and a storage system 208 connected via a network 210. System 200 may also include a fabrication facility 212 that is configured to produce integrated circuits designed according to the processes described herein. As shown in FIG. 2, each of computing devices 202, 204 and 206 may include one or more processors, memory, data and instructions.

By way of example, the one or more processors may be any conventional processors, such as commercially available central processing units (CPUs), graphical processing units (GPUs) or tensor processing units (TPUs). Alternatively, the one or more processors may include a dedicated device such as an ASIC or other hardware-based processor. As shown in FIG. 2, the memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

Moreover, reference to “one or more processors” herein includes situations where a set of processors may be configured to perform one or more operations. Any combination of such a set of processors may perform individual operations or a group of operations. This may include two or more CPUs, GPUs or TPUs (or other hardware-based processors) or any combination thereof. It may also include situations where the processors have multiple processing cores. Therefore, reference to “one or more processors” does not require that all processors (or cores) in the set must each perform all of the operations. Rather, unless expressly stated, any one of the one or more processors (or cores) may perform different operations when a set of operations is indicated, and different processors (or cores) may perform specific operations, either sequentially or in parallel.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance.

The data may be retrieved, stored or modified by the processor in accordance with the instructions. For instance, although the claimed subject matter is not limited by any particular data structure, the data may be stored in computing device registers, in a relational database as a table having a plurality of different fields and records, XML documents or flat files, HDL information, GDSII information, etc. The data may also be formatted in any computing device-readable format.

The computing devices may include all of the components normally used in connection with a computing device such as the processor and memory described above as well as a user interface having one or more user inputs (e.g., one or more of a button, mouse, keyboard, touch screen, gesture input and/or microphone), various electronic displays (e.g., a monitor having a screen or any other electrical device that is operable to display information), and speakers. The computing devices may also include a communication system having one or more wired or wireless connections to facilitate communication with other computing devices of system 200 and/or the fabrication facility 212.

The various computing devices may communicate directly or indirectly via one or more networks, such as network 210. The network 210 and any intervening nodes may include various configurations and protocols including short range communication protocols such as Bluetooth™, Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 202 may include one or more server computing devices having a plurality of computing devices, e.g., a load balanced server farm or cloud computing architecture, which exchange information with different nodes of a network for the purpose of receiving, processing, and transmitting the data to and from other computing devices. For instance, computing device 202 may include one or more server computing devices that are capable of communicating with computing devices 204, 206 and the fabrication facility 212 via the network 210. In some examples, client computing device 204 may be an engineering workstation used by a developer to perform circuit design and/or other processes for integrated circuit design and fabrication. Client computing device 206 may also be used by a developer, for instance to prepare system requirements for the integrated circuit or manage the manufacturing process with the fabrication facility 212.

Storage system 208 can be of any type of computerized storage capable of storing information accessible by the server computing devices 202, 204 and/or 206, such as a hard-drive, memory card, ROM, RAM, DVD, CD-ROM, flash drive and/or tape drive. In addition, storage system 208 may include a distributed storage system where data is stored on a plurality of different storage devices which may be physically located at the same or different geographic locations. Storage system 208 may be connected to the computing devices via the network 210 as shown in FIG. 2, and/or may be directly connected to or incorporated into any of the computing devices.

Storage system 208 may store various types of information. For instance, the storage system 208 may store a standard cell library and transistor-level netlists. It may also maintain functions for logic optimization, partitioning, lower-level routing and upper-level routing, as well as for performing technology mapping and other processes described herein.

### Transistor Placement Partitioning

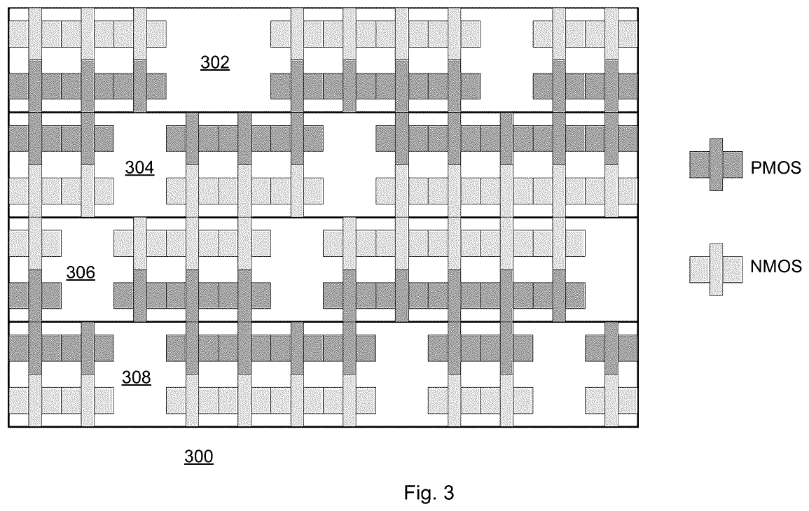

FIG. 3 illustrates an example of a transistor placement 300 in accordance with aspects of the technology. A transistor placement, such as the transistor placement 300 can require all transistors of a given transistor-level netlist to be placed within a design canvas without any two transistors overlapping. For two transistors that are placed adjacent to each other, the nets of their shared diffusion must be the same (also referred to herein as diffusion sharing).

By way of example, the transistor placement 300 includes four standard-cell rows 302, 304, 306 and 308. However, the disclosed technology is not limited to transistor placements having four standard cells, or including standard-cell rows. The disclosed technology can be applied to transistor placements having fewer than or more than four standard cells. The disclosed technology can be applied to transistor placements having standard-cell columns and/or standard-cell rows and transistor placements not including standard-cell columns and/or standard-cell rows. In FIG. 3, p-channel metal-oxide-semiconductor (PMOS) transistors are shown shaded darkly and n-channel metal-oxide-semiconductor (NMOS) transistors are shown shaded lightly.

Large-scale transistor-level routing may be challenging because of routing congestion. Routing strategies for lower layers (e.g., M2 layer and below) are different from routing strategies for upper layers (e.g., M2 layer and above).

Routing all transistors of a given placement directly within a macro-level design may have an extremely long runtime, such as hours, days or longer. To avoid such a long runtime, and thus for computational efficiency, approaches disclosed herein utilize layout partitioning at the physical level. A given transistor placement can be partitioned into several blocks based on connectivity of the transistors. Partitioning occurs at the physical level rather than at the logic level as in the standard-cell methodology, for instance. Partitioning a transistor placement can be based on locations of transistors within that placement, the quantity of transistors in that placement, and/or spacing between transistors of that placement. In some instances, partitioning a transistor placement can include dividing a placement into even-sized blocks. Partitioning at the logic level (e.g., without physical information) may constrain optimizations of PPA, whereas partitioning at the physical level does not suffer from this deficiency.

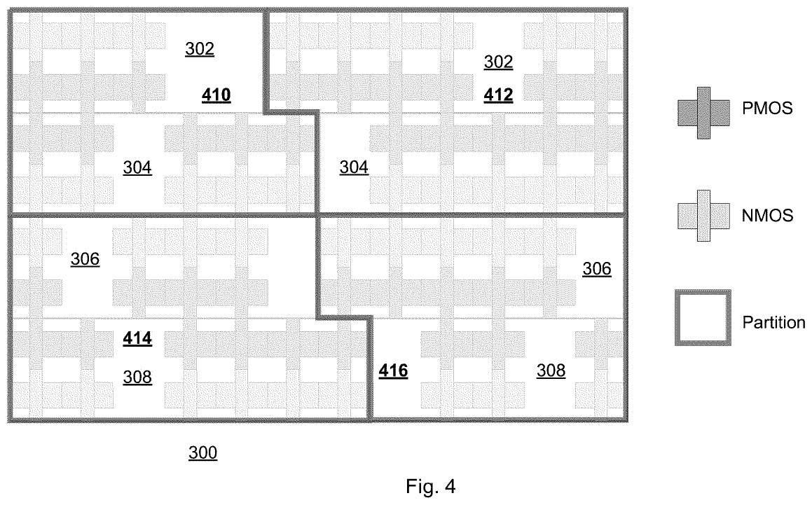

FIG. 4 illustrates an example of partitioning of the transistor placement 300 in accordance with aspects of the technology. The transistor placement 300 is partitioned into four blocks 410, 412, 414 and 416. As shown in FIG. 4, none of the blocks 410, 412, 414 and 416 split up grouping of channel-connected transistors (e.g., complementary metal-oxide semiconductor (CMOS) structures). The partitions 410, 412, 414 and 416 include portions of the standard-cell rows 302, 304, 306 and 308.

Based on a given partitioning of a transistor placement at the physical level into blocks, respective nets of transistors of a given block can be categorized as either intra-partition or inter-partition. As used herein, “intra-partition” refers to a net of transistors that connects terminals of those transistors exclusively within a single block. As used herein, “inter-partition” refers to a net of transistors that connects terminals of those transistors spanning multiple (e.g., at least two blocks). For a given net of transistors categorized as intra-partition (also referred to herein as an “intra-partition net”), connections of those transistors can be completed entirely within that block. In contrast, for a given net of transistors categorized as inter-partition (also referred to herein as an “inter-partition net”), at least one escape pin is needed for each block involved in that net of transistors.

### Lower-Level Routing

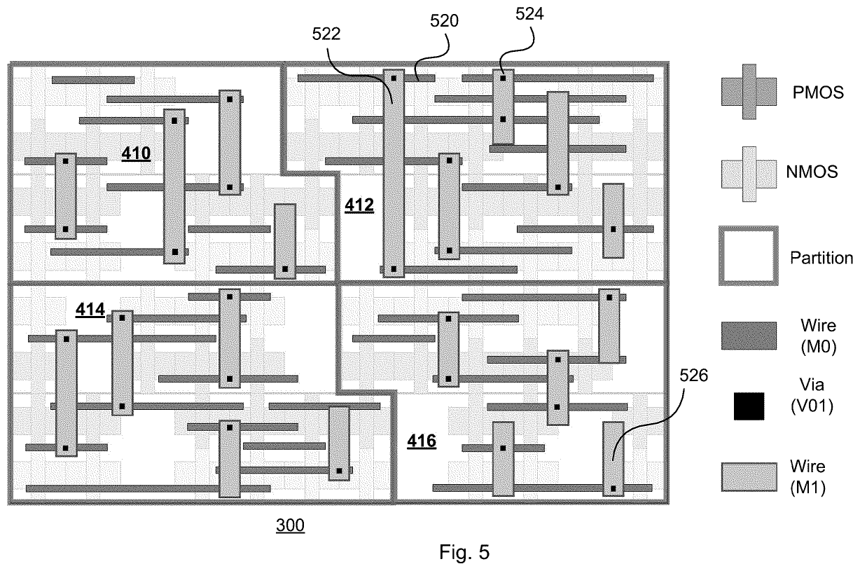

FIG. 5 illustrates an example of lower-layer routing of the partitioned transistor placement 300 in accordance with aspects of the technology. Lower-layer routing of a partitioned transistor placement can include routing intra-partition nets and determining escape pins for each block to be used with those intra-partition nets. By way of example, FIG. 5 illustrates a metal layer (M0) including connections of transistors within blocks in one orientation (e.g., horizontal) shown in blue (e.g., wire 520) By way of example, FIG. 5 illustrates another metal layer (M1) including connections of transistors within blocks in another orientation (e.g., vertical) shown in green (e.g., wire 522). The technology disclosed herein is not limited to metal layers including connections in a horizontal or vertical orientation. The technology disclosed herein is not limited to a metal layer including connections in one orientation being above or below another metal layer including connections in another orientation. Here, escape pins are coupled to connections of the metal layers M0 and M1 using vias (V01) formed therethrough, which are represented, in FIG. 5, as black squares (e.g., via 524). Here, wires in the M1 metal layer having only one via connected thereto, such as wire 526, are escape pins.

Upper-layer routing of a partitioned transistor placement can include routing inter-partition nets. Upper-layer routing can include connecting one or more intra-partition nets in one block to one or more intra-partition nets in another block. Although not illustrated in FIG. 5, connections of intra-partition nets can be in yet another metal layer (M2). Lower-level routing may be performed before upper-level routing; however, the disclosed technology is not so limited. As described above, lower-level routing includes determining at least one escape pin in each inter-partition. Upper-level routing connects these escape pins from the blocks corresponding to each inter-partition net.

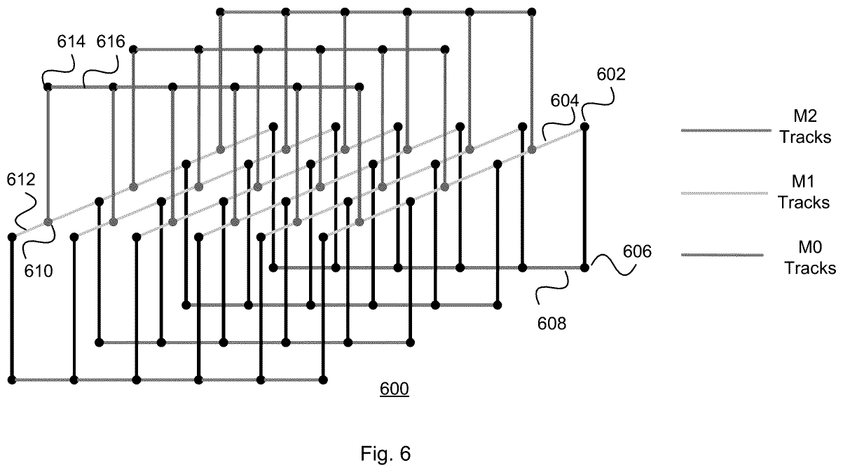

FIG. 6 illustrates an example of a routing grid graph 600 in accordance with aspects of the technology. A routing grid graph, such as the routing grid graph 600, can be utilized for lower-layer routing. Orientation of routing on a given layer may be unidirectional (e.g., vertical, horizontal). Orientations of routing can alternate for each layer (e.g., M0 being horizontal, M1 being vertical, M2 being horizontal, etc.). A given layer can include one or more tracks. Nodes of the routing grid graph 600 are intersection points of tracks of a metal layer to tracks of another metal layer above or below. By way of example, node 602 of track 604 of the M1 layer is an intersection point for node 606 of track 608 of the M1 layer. By way of example, node 610 of track 612 of the M1 layer is an intersection point for node 614 of track 616 of the M2 layer. Boundaries (e.g., edges) of a metal layer of a routing grid graph can have varying physical lengths, because, for example, the tracks may be non-uniform. In the routing grid graph 600, the M1 metal layer is a power rail and escape pins are only on the M1 metal layer. However, the disclosed approaches are not limited to escape pins being on just one metal layer or just the M1 metal layer.

Although not illustrated, to ensure connectivity of all nets of transistors, a flow network can be generated. In a flow network, each node of a corresponding routing grid graph, such as the routing grid graph 600, can be designated as a vertex. A flow network can include a pair of directed edges for each edge of the corresponding routing grid graph. The pair of directed edges together connect two vertices of the flow graph bidirectionally.

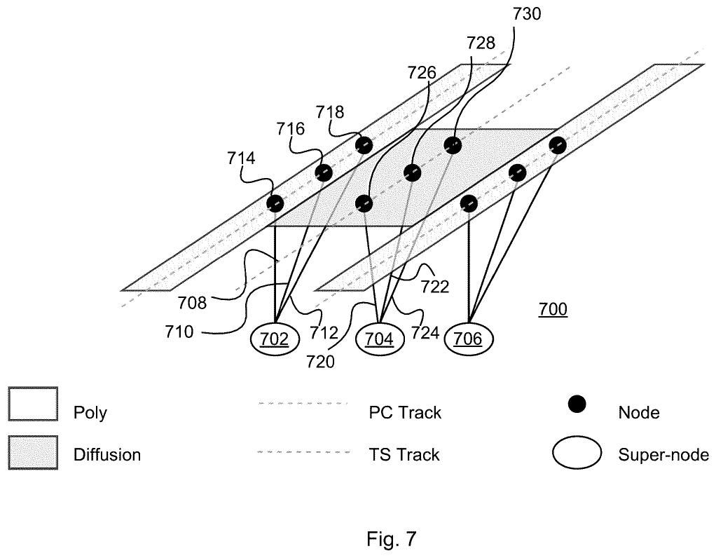

FIG. 7 illustrates an example of a flow network 700 including super-nodes 702, 704 and 706 in accordance with aspects of the technology. For a given terminal (e.g., diffusion, gate) of a transistor placement, there may be multiple vertices of a flow network available for connection to that terminal. Terminals that are not connected to a power or ground net, can be coupled to a super-node, such as the super-node 702, 704 or 706. A super-node includes multiple vertices (e.g., access points) of a routing grid graph.

For each net of transistors of a transistor placement, a terminal of that net can be designated as a source and another terminal of that net can be designated as a sink. It does not matter which terminal of a net is designated as a source or which terminal is designated as a sink. For a terminal of a net of transistors that is designated as a source, a respective edge is generated, in the routing grid graph, from a super-node to each vertex associated with that terminal. By of way example, directed edges 708, 710 and 712 are generated, in the routing grid graph 700, from super-node 702 to vertices 714, 716 and 718, respectively. Conversely, for a terminal of a net of transistors that is designated as a sink, a respective edge is generated, in the routing grid graph, from each vertex associated with that terminal to a super-node. By way of example, directed edges 720, 722 and 724 are generated, in the routing grid graph 700, from super-node 704 to vertices 726, 728 and 730, respectively.

For an external net of transistors, an escape pin can be generated to provide a connection of that escape pin to one or more pins in other blocks of a partitioned transistor placement. As used herein, “external net of transistors” refers to an inter-partition net of transistors or an I/O net of transistors of a transistor placement. Thus, a flow network can include an escape vertex and a directed edge from each vertex on escape layers (e.g., the M1 metal layer) to the escape vertex. Escape vertices can correspond to sinks for external nets.

CP-SAT can be used for lower-level routing. Constraints for CP-SAT can include connectivity constraints and design rule constraints. Connectivity constraints ensure interconnection of nets of transistors, which includes generation of a respective escape pin for each external net. These connectivity constraints can be based on a flow network. Design rule constraints prevent violations of design rules, which are based on an undirected graph obtained from the flow network by removing edge directions.

TABLE 1
provides descriptions of symbols used herein:

| Symbol | Description |
|---|---|
| N | The set of all nets. |
| V/A/E | The set of all vertices/arcs/edges. |
| ${V}_{u}^{i} / {V}_{u}^{o}$ | The set of vertices where vertex u has an in/out arc. |
| a_{u,v} | Boolean. Indicate if arc (u, v) is selected. |
| f_{u,v} | Integer. Flow on a_{u,v}. |
| sₙ | The source node for net n. |
| t_{n,i} | The i^{th} sink node for net n. |
| Tⁿ | The set of sink nodes for net n. |
| cᵤ | Integer. The encoding of vertex u. |
| e_{u,v} | Boolean. Indicate if edge (u, v) is selected. |
| Nᵤ | The set of neighbor vertices of vertex u. |
| m_{u,i} | Boolean. Indicate if all the edges in the i^{th} edge combi- |
| | nation for vertex u are selected. |
| M_{u,i} | The set of edges in the i^{th} edge combination satisfying |
| | minimum area for vertex u. |
| Mᵤ | The set of edges combinations satisfying minimum area |
| | for vertex u. |

### Connectivity Constraints

To ensure connectivity of a net of transistors, a flow is provided from a source to all associated sinks. For flow conservation, the in-flow of a vertex must be the same as the out-flow for that vertex as shown in Eq. 1:

$$∀ u ∈ V ; {\sum }_{v ∈ {V}_{u}^{i}} f ( v , u ) = {\sum }_{v ∈ \text{?}} f ( u , v ) . \qquad ( 1 )$$

$$\text{?} \text{indicates text missing or illegible when filed}$$

The in-flow of a source is fixed to the quantity of sinks. The out-flow of a sink (excluding an escape vertex) is fixed to one. The in-flow and out-flow of an escape vertex are fixed to the quantity of external nets of transistors in a block. To ensure that each net of transistors is connected by a Steiner tree, at most one of in-arcs can be selected for each vertex as shown in Eq. 2:

$$∀ u ∈ V , {\sum }_{v ∈ {V}_{u}^{i}} {a}_{v , u} \leq 1. \qquad ( 2 )$$

To remove the direction of edges for the following design rule constraints, if arc (u, v) or arc (v, u) is selected, then edge (u, v) is selected as shown in Eq. 3:

$$∀ ( u , v ) ∈ A , {a}_{u , v} \to {e}_{u , v} . \qquad ( 3 )$$

Note that an arc is directed, but an edge is undirected.

The flow conservation ensures the connectivity of nets. However, a vertex or an edge can only be assigned to only one net of transistors. For vertex exclusiveness, each vertex has an integer encoding. By way of example, an index of a net of transistors can be used for encoding (e.g., 0, 1, . . . , |N|−1). Encoding of source and sink vertices (excluding escape vertices) can be fixed to their corresponding net index. If an edge (u, v) is selected, then its two vertices will have the same encoding as shown in Eq. 4:

$$∀ ( u , v ) ∈ E , {e}_{u , v} \to ( {c}_{u} = {c}_{v} ) . \qquad ( 4 )$$

Note that only vertex exclusiveness is constrained because edge exclusiveness is inherently satisfied.

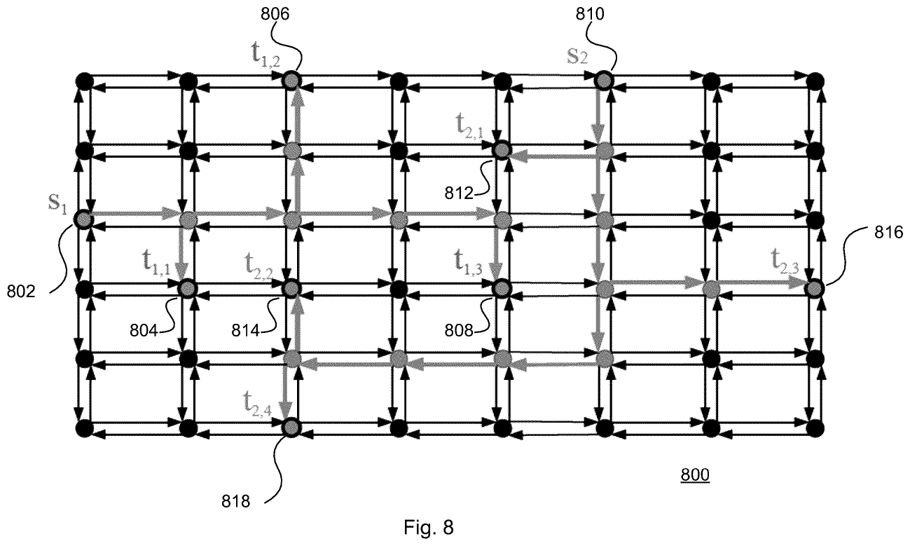

FIG. 8 illustrates an example of a Steiner tree 800 based on a flow network in accordance with aspects of the technology. Here, there are two nets of transistors, m shown in green and n₂ shown in purple. The net n₁ has four vertices to be connected. By way of example, vertex 802 of net n₁ is designated as a source vertex s₁, and the other three vertices 804, 806 and 808 are designated as sink vertices t_{1,1}, t_{1,2} and t_{1,3}, respectively. The net n₂ has five verices to be connected. By way of example, vertex 810 of net n₂ is designated as a source vertex s₂, and the other four vertices 812, 814, 816 and 818 are designated as sink vertices t_{2,1}, t_{2,2}, t_{2,3} and t_{2,4}, respectively.

As described above, connectivity constraints ensure that nets of transistors are connected with vertex exclusiveness and edge exclusiveness. However, these connectivity constraints do not address design rules. Thus, design rule constraints can be used to ensure that design rules are satisfied. Connectivity constraints are based on a directed (vertex-arc) graph whereas design rule constraints are based on an undirected (vertex-edge) graph. Non-limiting examples of design rule constraints include minimum area, end-of-line (EOL) spacing, via spacing, and parallel run length (PRL) spacing.

### Minimum Area Constraints

Minimum area constraints require each feature (e.g., metal shape) to be have at least a minimum threshold area. For unidirectional routing, a minimum area constraint corresponds to a minimum length of a wire, which can be derived from a given wire width. For a given vertex, if at least one of its edges is selected, then that vertex must have a minimum length. For each vertex u to satisfy a minimum area requirement, there may be several edge combinations, denoted as Mᵤ. An auxiliary variable m_{u,i} may be introduced to imply that all the edges in M_{u,i} are selected as shown in Eq. 5:

$$∀ i ∈ {M}_{u} , {m}_{u , i} \to ( {⋁}_{( {v}_{1} . {v}_{2} ) ∈ {M}_{u , i}} {e}_{{v}_{1} , {v}_{2}} ) . \qquad ( 5 )$$

Thus, if a vertex has an edge that is selected, at least one of the edge combinations must be also selected as shown in Eq. 6:

$$∀ u ∈ V , ( {⋁}_{v ∈ {N}_{u}} {e}_{u , v} ) \to ( {⋁}_{i ∈ {M}_{u}} {m}_{u , i} ) . \qquad ( 6 )$$

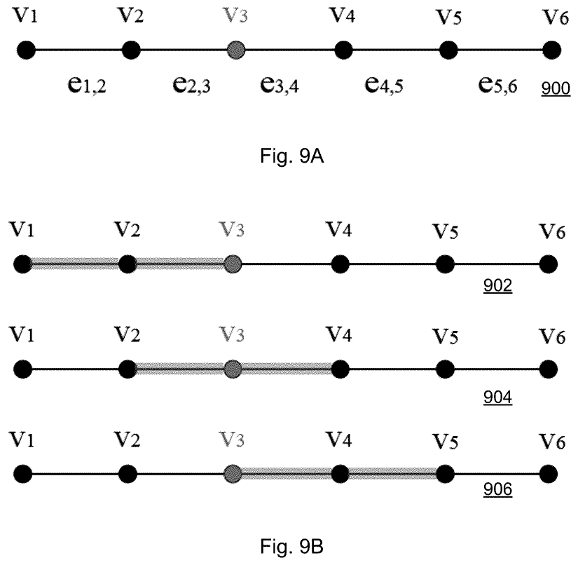

FIG. 9A illustrates an example 900 of minimum area constraints for vertex v₃ in accordance with aspects of the technology. By way of example, assume that the minimum length of a wire (e.g., per design rules) is two and all edges have a length of one. FIG. 9B illustrates examples 902, 904 and 906 of edge combinations for vertex v₃ in accordance with aspects of the technology and as shown in Eq. 7:

$$\begin{matrix}{m}_{3 , 1} \to ( {e}_{1 , 2} ⋀ {e}_{2 , 3} ) , \\ {m}_{3 , 2} \to ( {e}_{2 , 3} ⋀ {e}_{3 , 4} ) , \\ {m}_{3 , 3} \to ( {e}_{3 , 4} ⋀ {e}_{4 , 5} ) .\end{matrix} \qquad ( 7 )$$

If at least one edge associated with vertex v₃ is selected, then at least one of the edge combination variables for vertex v₃ must be true as shown in Eq. 8:

$$( {⋁}_{v ∈ {N}_{u}} {e}_{u , v} ) \to ( {m}_{3 , 1} ⋁ {m}_{3 , 2} ⋁ {m}_{3 , 3} ) . \qquad ( 8 )$$

Note that an edge combination variable can be used for one or more other vertices as long as those vertices share the same edge combination.

### EOL Spacing Constraints

EOL spacing constraints ensure a minimum spacing at the end of a wire. For unidirectional routing, an EOL spacing constraint corresponds to a minimum length between any two wires on the same track. For two wire edges e and e′ that are on the same track and have an insufficient length between them, all the wire edges between them must be true as shown in Eq. 9:

$$∀ e , {e}^{′} . ( e ⋀ {e}^{′} ) ( {⋀}_{{e}^{″} between e and {e}^{′}} {e}^{″} ) \qquad ( 9 )$$

Each wire edge pair on the same track that is separated by an insufficient length will be merged. Therefore, Eq. 9 ensures that disjointed wires on the same track are separated by at least a minimal spacing or length (e.g., per design rules).

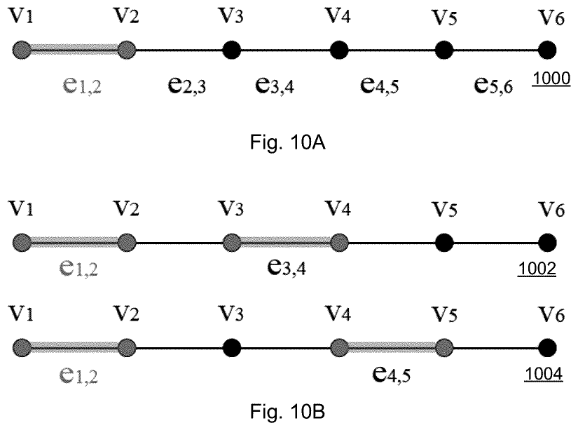

FIG. 10A illustrates an example 1000 of EOL spacing constraints for wire edge e_{1,2} between vertices v₁ and v₂ in accordance with aspects of the technology. By way of example, assume that the minimum length derived from EOL spacing constraint is three. FIG. 10B illustrates examples 1002 and 1004 of wire edges e_{3,4} and e_{4,5} that need to be constrained in accordance with aspects of the technology and as shown in Eq. 10:

$$\begin{matrix}( {e}_{1 , 2} ⋀ {e}_{3 , 4} ) \to {e}_{2 , 3} , \\ ( {e}_{1 , 2} ⋀ {e}_{4 , 5} ) \to ( {e}_{2 , 3} ⋀ {e}_{3 , 4} ) .\end{matrix} \qquad ( 10 )$$

By way of example, an objective of the disclosed lower-layer routing is to reduce or minimize the total wire length and/or via cost. Each edge of a routing grid graph is either a wire or a via. The cost associated with a given wire edge on a layer can be derived by the length of that wire edge multiplied by a unit-length cost on that layer. The unit-length cost can be a user-defined parameter. The cost associated with a given via edge on multiple layers can be a user-defined parameter. By way of example, an objective used in CP-SAT can be formulated as shown in Eq. 11:

$${\sum }_{e ∈ E} {cost}_{e} . \qquad ( 11 )$$

Lower-level routing can be performed iteratively.

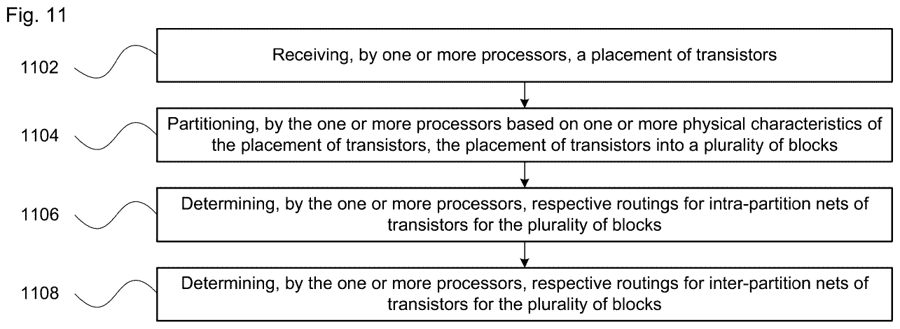

FIG. 11 illustrates an example method 1100 in accordance with the above discussion. The method 1100 includes, at block 1102, receiving, by one or more processors, a placement of transistors. At block 1104, the method 1100 includes partitioning, by the one or more processors based on one or more physical characteristics of the placement of transistors, the placement of transistors into a plurality of blocks. At block 1106, the method 1100 includes determining, by the one or more processors, respective routings for intra-partition nets of transistors for the plurality of blocks. At block 1108, the method 1100 includes determining, by the one or more processors, respective routings for inter-partition nets of transistors for the plurality of blocks.

Although the technology herein has been described with reference to particular embodiments and configurations, it is to be understood that these embodiments and configurations are merely illustrative of the principles and applications of the present technology. It is therefore to be understood that numerous modifications may be made to the illustrative embodiments and configurations, and that other arrangements may be devised without departing from the spirit and scope of the present technology as defined by the appended claims.

1. A method, comprising:
receiving, by one or more processors, a placement of transistors;
partitioning, by the one or more processors based on one or more physical characteristics of the placement of transistors, the placement of transistors into a plurality of blocks;
determining, by the one or more processors, respective routings for intra-partition nets of transistors for the plurality of blocks; and
determining, by the one or more processors, respective routings for inter-partition nets of transistors for the plurality of blocks.

2. The method of claim 1, wherein the one or more physical characteristics of the placement of transistors include at least one of locations of transistors within the placement of transistors, a quantity of transistors of the placement of transistors, or a spacing between transistors of the placement of transistors.

3. The method of claim 1, wherein the one or more physical characteristics of the placement of transistors include a connectivity of transistors of the placement of transistors.

4. The method of claim 1, wherein determining the respective routings for the intra-partition nets of transistors includes determining respective escape pins for the plurality of blocks.

5. The method of claim 4, wherein determining the respective routings for the inter-partition nets of transistors includes determining respective connections of the escape pins for the inter-partition nets of transistors.

6. The method of claim 1, wherein determining the respective routings for the intra-partition nets of transistors includes generating respective routing grid graphs for the inter-partition nets of transistors.

7. The method of claim 6, wherein determining the respective routings for the intra-partition nets of transistors further includes generating respective flow networks corresponding to the routing grid graphs.

8. The method of claim 7, wherein determining the respective routings for the intra-partition nets of transistors further includes generating respective Steiner trees corresponding to the flow networks.

9. The method of claim 1, wherein determining the respective routings for the intra-partition nets of transistors is based on connectivity constraints.

10. The method of claim 1, wherein determining the respective routings for the intra-partition nets of transistors is based on design rule constraints.

11. The method of claim 10, wherein the design rule constraints include at least one of minimum area constraints, end-of-line (EOL) spacing constraints, via spacing constraints, or parallel run length (PRL) spacing constraints.

12. The method of claim 1, further comprising, responsive to determining the respective routings for the intra-partition and the respective routings for the inter-partition nets, generating a routing result.

13. The method of claim 12, further comprising causing fabrication of an integrated circuit using the routing result.

14. A system, comprising:
memory configured to store a placement of transistors for a semiconductor device to be fabricated; and
one or more processors operatively coupled to the memory, the one or more processors being configured to:
partition, based on one or more physical characteristics of the placement of transistors, the placement of transistors into a plurality of blocks;
determine respective routings for intra-partition nets of transistors for the plurality of blocks; and
determine respective routings for inter-partition nets of transistors for the plurality of blocks.

15. The system of claim 14, wherein the one or more physical characteristics of the placement of transistors include at least one of locations of transistors within the placement of transistors, a quantity of transistors of the placement of transistors, or a spacing between transistors of the placement of transistors.

16. The system of claim 14, wherein the one or more physical characteristics of the placement of transistors include a connectivity of transistors of the placement of transistors.

17. The system of claim 14, wherein the one or more processors are configured to determine the respective routings for the intra-partition nets of transistors by being configured to determine respective escape pins for the plurality of blocks.

18. The system of claim 14, wherein the one or more processors are configured to determine the respective routings for the intra-partition nets of transistors by being configured to generate respective routing grid graphs for the inter-partition nets of transistors.

19. The system of claim 14, wherein the one or more processors are further configured to determine the respective routings for the intra-partition nets of transistors based on connectivity constraints.

20. The system of claim 14, wherein the one or more processors are further configured to determine the respective routings for the intra-partition nets of transistors based on design rule constraints.

21. The system of claim 14, wherein the one or more processors are further configured to, responsive to determination of the respective routings for the intra-partition and the respective routings for the inter-partition nets, generate a routing result.

22. The system of claim 14, wherein the one or more processors are further configured to cause fabrication of the semiconductor device using the routing result.
